(19) United States
(12) Patent Application Publication
(10) Pub. No.: US 2005/0014019 A1
(43) Pub. Date: Jan. 20, 2005

(54) Method of selecting a charge transport and/or anti-quenching material

(76) Inventor: Ying Wang, Wilmington, DE (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 10/623,042

(22) Filed: Jul. 18, 2003

(51) Int. Cl. G01N 21/00; H05B 33/00

(52) U.S. Cl. 428/690; 428/917; 313/504; 73/866; 257/40

(57) ABSTRACT

A method for selecting charge transport and/or anti-quenching materials is presented. The method includes determining a first luminescence intensity I₀ of a luminescent material in the absence of the charge transport and/or anti-quenching material, determining a second luminescence intensity I_{q} of the luminescent material in the presence of the charge transport and/or anti-quenching material, and comparing the first luminescence intensity I₀ with the second luminescence intensity I_{q} to determine a luminescence quenching constant of the charge transport and/or anti-quenching material with respect to the luminescent material. A device made using charge transport and/or anti-quenching material selected using the selection method and a kit to practice the selection method.

### FIELD OF THE INVENTION

The present invention relates generally to charge transport and/or anti-quenching materials and specifically to the selection of charge transport and/or anti-quenching materials useful in organic electronic devices.

### BACKGROUND INFORMATION

Organic electronic devices that emit light, such as organic light-emitting diodes (OLEDs) used in display devices, are currently used in many different kinds of electronic equipment. In all such devices, an organic active layer is sandwiched between two electrical contact layers. The organic active layer emits light through the light-transmitting electrical contact layer when a voltage is applied across the electrical contact layers. At least one of the electrical contact layers is light-transmitting (transparent) so that light can pass through the electrical contact layer and escape the device. Some organic electroluminescent compounds that make up the active component in light-emitting diodes include small molecules, such as organometallic complexes and dyes, and conjugated polymers.

Devices that use small molecule light-emitting materials frequently include one or more charge transport and/or anti-quenching layers, which are typically positioned between the light-emitting layer and one of the contact layers. A charge transport layer may be a hole transport layer or an electron transport layer. A hole transport layer may be positioned between the light-emitting layer and the anode contact layer which provides holes into the light-emitting layer. An electron transport layer may be positioned between the light-emitting layer and the cathode contact layer, which injects electrons into the light-emitting layer.

Currently, there is no efficient way of distinguishing charge transport and/or anti-quenching materials that are suitable from charge transport and/or anti-quenching materials that are not. Thus, selecting a hole and/or electron transport material (aka, a charge transport) involves repeatedly building different charge transport and/or anti-quenching materials into devices to accumulate trial-and-error results.

What is needed is a method for distinguishing transport materials that are suitable from transport materials that are not suitable without the laborious process of building each candidate material into a device.

### SUMMARY OF THE INVENTION

A charge transport and/or anti-quenching material is selected by the method of
(a) determining a first luminescence intensity I₀ of a luminescent material in the absence of the charge transport and/or anti-quenching material;
(b) determining a second luminescence intensity I_{q} of the luminescent material in the presence of the charge transport and/or anti-quenching material; and
(c) comparing the first luminescence intensity 10 with the second luminescence intensity I_{q} to determine a degree of luminescence quenching of the charge transport and/or anti-quenching material with respect to the luminescent material; and
(d) determining whether the degree of quenching is appropriate for the desired use of said charge transport and/or anti-quenching material.

In another aspect, the invention includes an electronic device that includes a luminescent material, an electrode, and a charge transport and/or anti-quenching material selected by the above described method.

In another aspect of the invention, is a kit is provided to permit ease of practice in selection method comprising a means for holding one or more containers or compartments therein in 10⁻⁶ to 10⁻² Molar of the light-emitting material; a dropper, pipette, or other means to control the dispensing of between 10⁻7 to 2 Molar of the charge transport and/or anti-quenching material to be selected into said containers; and a light source such as xenon, tungsten lamp; and optionally, a detector, including a charge coupled device (“CCD”) camera. The containers or compartments is preferably glass, metal, or a plastic known not to interact with light-emitting material or organic charge transport or anti-quenching materials.

The present kits will also typically include means for packaging the container means and the administering the method means. Such packaging means may take the form of a cardboard or paper box, a plastic or foil pouch, etc. The present kits will also usually include written instructions which describe how to dispense the material, expose the material to the light into the container and detect the luminescence of the composition. It is to be understood that the written instructions may be on any of the container means, the administering means, or the packaging means, in addition to being present on a separate piece of paper.

### BRIEF DESCRIPTION OF THE DRAWINGS

FIG. 1A is a flowchart illustrating a selection process for charge transport and/or anti-quenching materials.

FIG. 1B is a perspective view of an exemplary 5×5 array used for combinatorial screening.

FIG. 1C is a flowchart illustrating a combinatorial selection process in accordance with the invention.

FIG. 2A is a graph depicting the luminescence quenching behavior of Emitter I by (bis[4-(N,N-diethylamino)-2-methylphenyl](4-methylphenyl)methane) (“MPMP”).

FIG. 2B is a graph of I_{q}/I₀ versus MPMP concentration based on the data in FIG. 2A.

FIG. 3A is a graph depicting the luminescence quenching behavior of Emitter I by (4,4′-bis[N-(1-naphthyl)-N-phenyl-amino]-biphenyl) (“NBP”).

FIG. 3B is a graph of I_{q}/I₀ versus NPB concentration based on the data in FIG. 3A.

FIG. 4 is a graph depicting the Stern-Volmer quenching behavior for different hole transport materials.

FIG. 5 depicts an exemplary electronic device that may be implemented with the selection process of FIG. 1A.

### DETAILED DESCRIPTION

Unless otherwise defined, all technical and scientific terms used herein have the same meaning as commonly understood by one of ordinary skill in the art to which this invention belongs.

As used herein, an “emitter”, “luminescent material”, or “photoactive” is a material that emits light when activated by an applied voltage (such as in a light-emitting diode or light-emitting electrochemical cell) or in response to radiant energy. These materials are activated by an applied voltage (such as in a light-emitting diode or light-emitting electrochemical cell), or a layer of material that responds to radiant energy and generates a signal with or without an applied bias voltage (such as in a photodetector).

Emitters include both fluorescent (including tris(8-hydroxyquinolato)aluminum(III) AlQ₃, and light emitting polymers) and phosphorescent materials (including organometallic Tris (2-(4-fluorophenyl)-5-trifluoromethylpyridine)Ir(I II) (“DPA”), and 4,9-diphenyl-phenanthroline. An “organometallic compound” is a compound having a metal-carbon bond. The organometallic compound may include metal atoms from Groups 3 through 15 of the Periodic Table. The IUPAC numbering system is used throughout, where the groups from the Periodic Table are numbered from left to right as 1 through 18 (CRC Handbook of Chemistry and Physics, 81^{st} Edition, 2000) and mixtures thereof. In one embodiment, the metal atoms are from Groups 8 through 11. In one embodiment, the metal atoms are of atomic number between 71 and 83, such as platinum, Rhenium, Gold, and iridium atoms. Complexes of iridium with phenylpyridine, phenylquinoline, or phenylpyrimidine ligands have been disclosed as electroluminescent compounds in PCT Application 02/02714. Other organometallic complexes have been described in, for example, Applications such as US 2001/0019782, EP 1191612, WO 02/15645, and EP 1191614. Electroluminescent devices with an active layer of polyvinyl carbazole (PVK) doped with metallic compounds of iridium have been described by Burrows and Thompson in published PCT applications WO 00/70655 and WO 01/41512. Electroluminescent emissive layers comprising a charge carrying host material and a phosphorescent platinum compound have been described in U.S. Pat. No. 6,303,238. Analogous tetradentate platinum compounds can also be used. These electroluminescent complexes may be used alone or doped into charge-carrying hosts.

As used herein, the phrase “charge transport material” is intended to mean material that can receive a charge from an electrode and facilitates movement through the thickness of the material with relatively high efficiency and small loss of charge. A “hole transport material” is a type of charge transport material capable of receiving a positive charge and transporting it from the anode. An “electron transport material,” which is another type of charge transport material, receives and transport negative charges.

“Anti-quenching” material means a material that prevents, retards or diminishes both the transfer of energy and the transfer of electron from the excited state of the photoactive layer to an adjacent layer.

The present invention provides a means to use a luminescence material to select a charge transport and/or anti-quenching material which may have applications in devices beyond those using a luminescence material. Organic electronic devices that may have need for a charge transport or anti-quenching material selected by the method described herein include a device having one or more semiconductor layers or materials. Organic electronic devices include: (1) devices that convert electrical energy into radiation (e.g., a light-emitting diode, light-emitting diode display, or a diode laser); (2) devices that detect signals through electronics processes (e.g., photodetectors (e.g. photoconductive cells, photoresistors, photoswitches, phototransistors, phototubes), IR detectors); (3) devices that convert radiation into electrical energy (e.g., photovoltaic device or solar cell): and devices that include one or more electronic components that include one ore more semi-conductor layers (e.g., a transistor or diode).

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present). Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Group numbers corresponding to columns within the periodic table of the elements use the “New Notation” convention as seen in the CRC Handbook of Chemistry and Physics, 81^{st} Edition (2000).

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

Whether a particular charge transport and/or anti-quenching material provides good or poor device performance depends on the composition of the charge transport and/or anti-quenching material and on the particular application of interest. For example, in some applications, a “good” performance may include emission of light at the highest possible intensity level. The intensity level is typically measured in cd/m². On the other hand, in other applications, a “good” performance may include emission of light at the highest efficiency level. Efficiency can be either current efficiency or power efficiency. Current efficiency is the light output divided by the current density applied, typical unit is cd/A. Power efficiency is the light output divided by the power applied, typical unit is Im/W. However, regardless of the application, device performance is adversely affected if the luminescence of the emitting material is quenched by the charge transport and/or anti-quenching material.

“Quenching,” as used herein, refers to a reduction in the luminescent intensity of the luminescent material. A charge transport material having a high luminescence quenching rate constant causes poor performance of a light-emitting device, while a charge transport material having a low luminescence quenching rate constant causes good device performance. For example, “MPMP”, which results in good device performance with organometallic iridium compound emitters, showed almost no luminescence quenching. In contrast, “NPB” and “TDATA” (4,4′,4″-tris(diphenylamino) triphenylamine), both of which may cause poorer device performance in certain devices and are effective quenchers with organometallic Ir emitters. This effect of the luminescence quenching rate constant on device performance indicates that charge transport materials can be pre-screened by determining their luminescence quenching rate constants.

The luminescence quenching of an excited molecule can be described as
A*+Q=X (1)
where A* represents the luminescent excited state of the emitter, Q represents the quencher (in this case the charge transport molecule under study), and X represents the product of the quenching reaction. The luminescence can be measured as electroluminescence or photoluminescence. In general, it is simpler and faster to measure photoluminescence. The degree of quenching can be evaluated quantitatively by determining the rate constant of the luminescence quenching, k_{q}, in the above equation. The value of K_{q} can be obtained, for example, by the well-known Stern-Volmer equation:
(I_{q}/I₀)−1=k_{q}T₀[Q] (2)
where I_{q} represents the luminescence intensity of the emitter in the presence of the quencher, I₀ represents the intensity in the absence of the quencher, T₀ is the luminescent excited state lifetime in the absence of the quencher, and [Q] is the concentration of the quencher. By plotting (I_{q}/I₀)−1 vs [Q], the slope of the straight line gives k_{q} T₀, which is known as the Stern-Volmer quenching constant. If T₀ is known, then one obtains the luminescence quenching rate constant, k_{q}. Even if the exact value of T₀ were unknown, the quenching rate constants of different charge transport and/or anti-quenching materials may be accurately compared because T₀ is a constant.

The degree of quenching can be evaluated qualitatively, by comparing the luminescence intensity of a sample with an emitter and a test quenching material to the luminescence intensity of a control sample. The control sample can be the emitter without any quenching material, or the emitter with a charge transport and/or anti-quenching material known to have a low quenching constant. This qualitative method can be used to screen large numbers of materials using combinatorial techniques.

Other features and advantages of the invention will be apparent from the following detailed description, and from the claims.

In a first embodiment, the invention relates to the selection of charge transport and/or anti-quenching materials for use in an OLED. The performance and lifetime of OLED devices, whether vapor deposited or solution deposited, depend on the charge transport and/or anti-quenching materials that are used. The performance and lifetime of OLED devices are especially sensitive where the excited state lifetimes of the emitters are long, including but not limited to iridium (Ir)- and platinum (Pt)- based OLED devices that have lifetimes in the microsecond/sub-microsecond regime instead of in the nanosecond regime of fluorescent emitters. Thus, finding the suitable hole transport material and electron transport material is critical for achieving high efficiency OLED devices with long life spans.

In this invention, the selection of the charge transport and/or anti-quenching material is correlated to the luminescence quenching rate constants of the charge transport and/or anti-quenching material used in a device. For example, a charge transport material having a high luminescence quenching rate constant causes poor performance of a light-emitting device, while a charge transport material having a low luminescence quenching rate constant causes good device performance.

Since a high quenching rate constant indicates poor OLED device performance in this example, charge transport materials that have a high quenching rate constant can be eliminated without the time-consuming and laborious trial and error process. In one embodiment, the quenching rate constant is determined using, a fixed concentration of the charge transport and/or anti-quenching material is added to a solution containing the emitter molecule of interest under a substantially anaerobic condition. The oxygen concentration in the solution should be anaerobic, i.e., low enough such that the luminescence quenching rate due to oxygen is less than 10% of the luminescent excited state decay rate. For example, typical oxygen quenching rate constant is about 10¹⁰ M⁻¹ sec⁻¹, so if the excited state lifetime of an Iridium emitter is 1 microsecond, then the oxygen concentration is preferred to be lower than 10⁻5M. The concentration of the charge transport and/or anti-quenching material is preferably between 10⁻7 and 2 M, and more preferably between 10⁻⁶ and 0.1 M.

The luminescence intensity of the solution (which can be a mixture of more than one light-emitting material) in the presence of the charge transport and/or anti-quenching material is compared with the luminescence intensity of the solution in the absence of the charge transport and/or anti-quenching material. Stern-Volmer equation, (2), can be used to analyze the data quantitatively. If the luminescence intensity in the presence of the charge transport and/or anti-quenching material is lower than the luminescence intensity in the absence of the charge transport and/or anti-quenching material, the different luminescence intensities indicate that the particular charge transport and/or anti-quenching material has a high luminescence quenching constant, and would therefore lead to poor device performance. If the presence of the charge transport and/or anti-quenching material does not affect the luminescence intensity, on the other hand, the particular charge transport and/or anti-quenching material has a low luminescence quenching rate constant. In general, a Stern-Volmer quenching constant less than 500 is judged to be low. Appropriate charge transport and/or anti-quenching material can then be selected based on its quenching rate constant and the application of use for the material. In this particular example, charge transport and/or anti-quenching materials with a Stern-Volmer quenching constant of less than 500 are selected; and those with a Stern-Volmer quenching constant of less than 100 being also selected.

In one embodiment, the comparison of photoluminescence intensity in the presence of the charge transport and/or anti-quenching material and in the absence of the charge transport and/or anti-quenching material may be done visually. Alternatively, various conventional methods for measuring or detecting photoluminescence intensity may be used, such as a photodiode for a single sample detection and Charge Coupled Device (CCD camera) for multi-sample parallel detection.

The following are illustrative examples of the present invention and are not to limit the scope of the invention described in the claims.

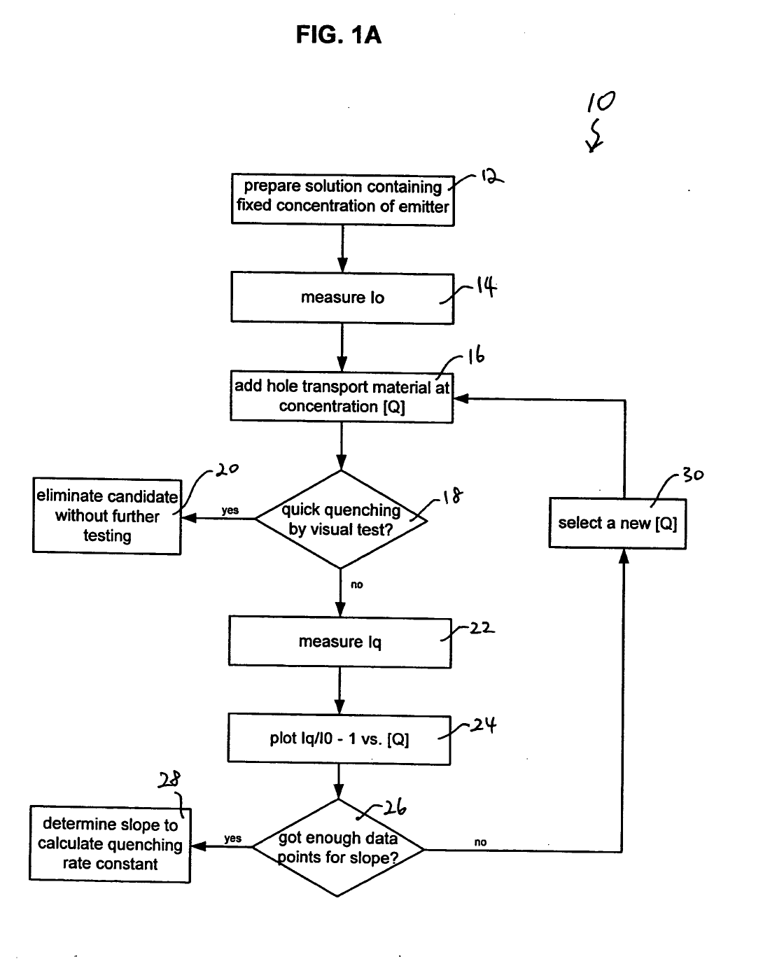

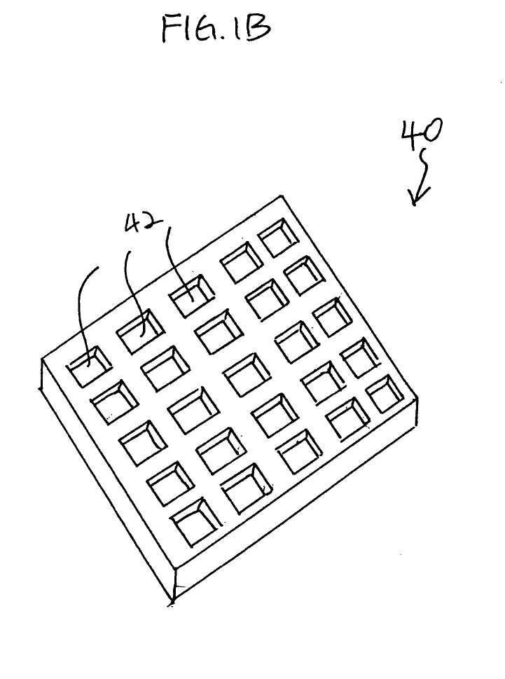

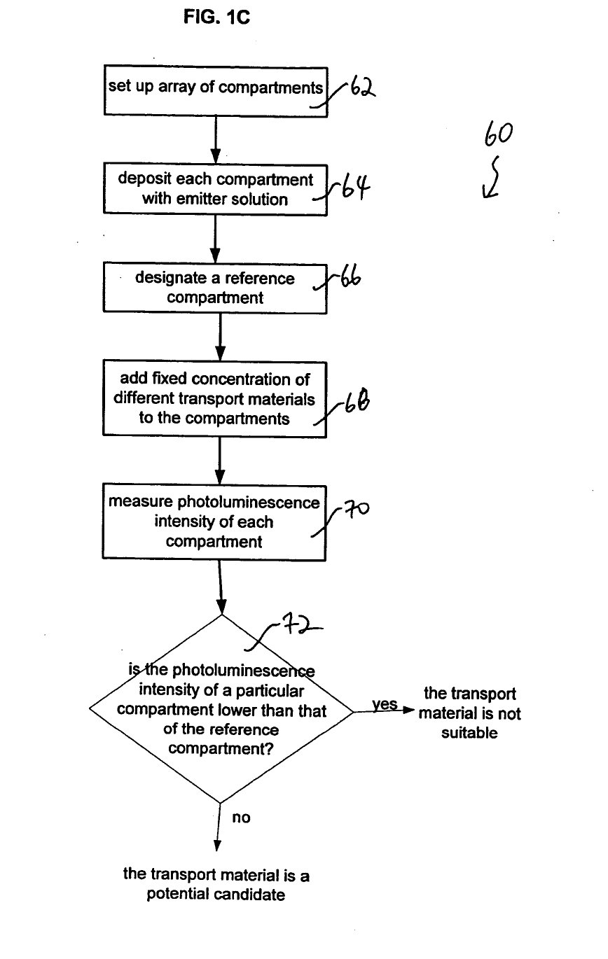

FIG. 1A is a flowchart illustrating a selection process 10 for charge transport materials. The selection process 10 begins with preparation of a solution that contains a predetermined concentration of an emitter molecule of interest, e.g., Tris (2-(4-fluorophenyl)-5-trifluoromethylpyridine)Ir(III) (“Emitter I”) (stage 12). The concentration of emitter in the solution may range between 10⁻⁶ M to 10⁻²M. I₀ is measured (stage 14). A known concentration [Q] of the charge transport/anti-quenching material is added to the solution (stage 16) and carefully observed for clear signs of luminescence quenching (stage 18). If luminescence is quenched, indicating that the charge transport material is not suitable for the particular emitter of interest, there is no need to subject the charge transport material through the empirical testing procedures (stage 20). On the other hand, if visual observation does not clearly indicate quick quenching, photoluminescence intensity is measured after the addition of the charge transport material (stage 22) to obtain I_{q}. Once I_{q} is obtained, a data point is marked on a plot of I_{q}/I₀−1 versus [Q] (stage 24). If there are enough data points on the plot to determine the slope (stage 26), then the slope, and therefore the Stern-Volmer quenching constant, is determined (stage 28). On the other hand, if there is not enough data points to determine the slope with a reasonable accuracy, then a new [Q] is selected (stage 30) and the selection process 10 is repeated from stage 16 with the new [Q] to produce another data point. The [Q] may be varied between 10⁻7 M to 2.0 M.

In some situations, it may be desirable to select a threshold value of the quenching rate constant to select charge transport and/or anti-quenching materials that generate a quenching rate constant lower than the threshold value. For example, one may decide not to use any charge transport and/or anti-quenching material that has a Stern-Volmer quenching constant higher than 500. The selectivity of the charge transport and/or anti-quenching material will increase as this threshold value is made smaller.

The method described here works for both electron and hole transport materials. The sensitivity and selectivity depend somewhat on the location of the electron-hole recombination zone. For example, in certain devices, the recombination zone in the emitter layer is closer to the hole transport layer, then the device efficiency is more sensitive to the properties of the hole transport material. Consequently, the threshold value of Stern-Volmer quenching constant for selecting hole transport material can be set lower but the threshold value for selection electron transport material can be set higher. In other devices, the recombination zone is closer to the electron transport layer, then the device efficiency is more sensitive to the properties of the electron transport material. Consequently, the threshold value of Stern-Volmer quenching constant for selecting electron transport material can be set lower but the threshold value for selection hole transport material can be set higher.

In another embodiment the charge transport and/or anti-quenching and/or anti-quenching material selection method described above which was scaled up to combinatorily screen a large number of charge transport and/or anti-quenching and/or anti-quenching materials in an efficient manner for an organic electronic device. To use this combinatorial method, a two-dimensional array of test solutions was prepared. Each compartment or vial in the array was filled with an emitter solution of interest, in this case a Emitter I solution at a concentration of approximately 10⁻⁴ M. Different charge transport materials were added to each compartment at a fixed concentration. The compartments may be extruded, shaped, pressed, or formed from any number of materials such as glass, metal, or plastics, and may exist as one or more units having multiple compartments. An alternative may be of any number of well known means for holding containers (each having one or more compartments, vials, wells, test tubes, etc. suitable for the test materials (i.e., glass, metal, or plastic known not to interact with light-emitting material, organic charge transport or anti-quenching material). The holding means can be a glass, metal, wood, beads, wire mesh, or plastic support structure and the compartments may be integral therewith or separate (and may or may not be removable from the support structure) suitable containers (e.g. glass, metal, or plastics that do not interact with the light-emitter, organic charge transport or anti-quenching materials) which can be placed therein while running the screening method.

One compartment was designated as the reference compartment, to which no transport material was added. Upon photo-illumination under anaerobic conditions, the photoluminescence of the emitter was detected, either visually or with a multi-channel photo detector such as a CCD camera. The compartment that showed substantially the same photoluminescence intensity as the reference solution, such as the MPMP compartment, indicated that very little quenching occurred in that compartment. The compartments that showed reduced photoluminescence intensity compared to the reference solution, such as the NPB compartment, indicated that too much quenching of the luminescence occurred to make the added charge transport and/or anti-quenching materials suitable for the OLED as currently constructed.

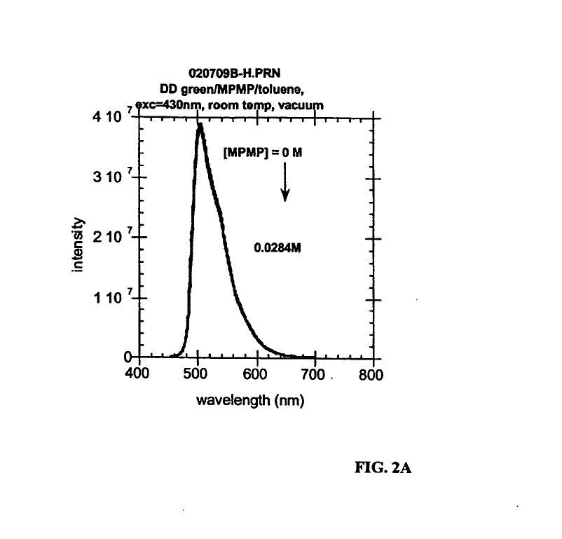

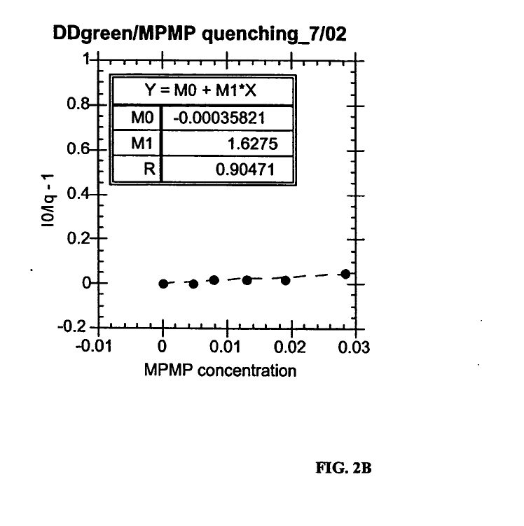

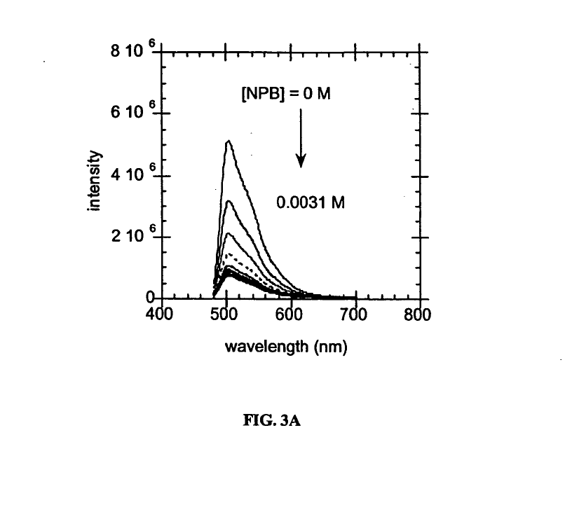

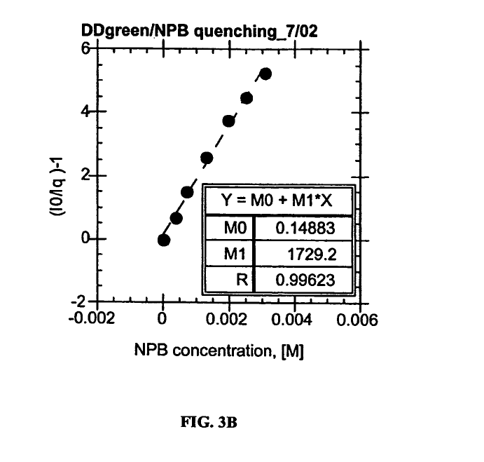

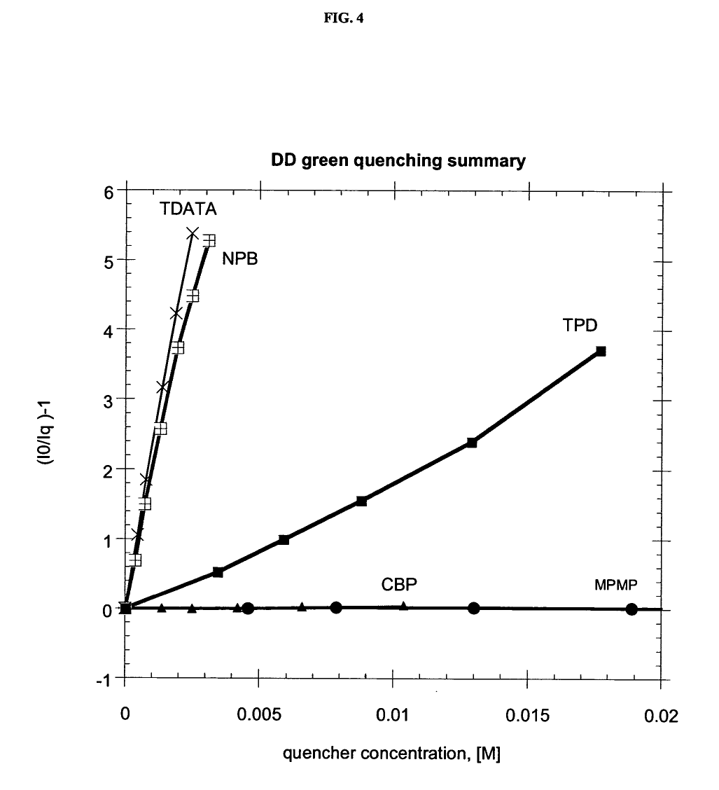

How much a reduction in photoluminescence intensity constitutes the threshold for rejecting a charge transport and/or anti-quenching material depends on the nature of the emitter and the concentration of the charge transport and/or anti-quenching material used. The threshold can be determined from the Stern-Volmer quenching curve, such as FIG. 2B or FIG. 3B. For example, if the Stern-Volmer quenching curve for a “bad” charge transport and/or anti-quenching material shows a 50% reduction in luminescence intensity at a charge transport and/or anti-quenching material concentration of 2×10⁻3M, then one can use 2×10⁻3M concentrations for all the charge transport and/or anti-quenching materials in all the compartments, and set a threshold for rejection at 50% reduction in luminescence intensity. One can lower this value to be more selective, or raise the value to be less selective. Using this method, high-quenching charge transport and/or anti-quenching materials were eliminated from the list of candidates to be built into the OLED.

FIG. 1B is the exemplary 5×5 testing array 40 that can be used for the combinatorial selection process. The testing array 40 may be made of any container suitable for holding the solutions to be tested, such as any of the conventional test trays. The testing array 40 is shown to have 25 compartments 42, allowing up to 25 different transport materials to be tested.

FIG. 1C is a flowchart illustrating a combinatorial selection process 60. As described above, the combinatorial selection process 60 begins by setting up an array of compartments (stage 62). An emitter solution of interest (e.g., a Emitter I solution of concentration between 10⁻3 M and 10⁻⁵ M) is prepared and distributed among the compartments (stage 64). A reference compartment is designated (stage 66), to which no charge transport and/or anti-quenching material is added. Then, a fixed concentration of different charge transport and/or anti-quenching materials are added to the different compartments, but not to the reference compartment (stage 68). After adding the charge transport and/or anti-quenching materials, photoluminescence intensity of each compartment is measured, visually or by using any of the well-known methods like a CCD camera (stage 70). The photoluminescence intensity of each non-reference compartment is compared to the photoluminescence intensity of the reference compartment, which contains no charge transport and/or anti-quenching material (stage 72). If the photoluminescence intensity of a particular compartment is lower than that of the reference compartment, that means the charge transport and/or anti-quenching material that was added to the particular compartment is a good quencher, and therefore a bad candidate for a device. Thus, the charge transport and/or anti-quenching material that was added to the compartment that produces a low photoluminescence intensity is eliminated from the list of candidates for the device. The threshold for rejection is described in the previous paragraph. The other charge transport and/or anti-quenching materials are potentially good candidates, and may be built into the device for further testing.

FIG. 2A is a graph of the luminescence quenching behavior of MPMP with Emitter I, which is an Ir-based emitter. The data of FIG. 2A was obtained by adding a fixed concentration of MPMP to a toluene solution containing Emitter I under anaerobic condition. When MPMP was added, the emitted light had a peak wavelength of approximately 500 nm and a peak intensity of around 3.9×10⁷ counts. With the addition of various concentrations of MPMP up to 0.0284 M, the intensity and the spectrum of Emitter I stayed virtually unchanged. This lack of change indicated that there is no significant quenching of Emitter I luminescence by MPMP.

FIG. 2B is a graph of I_{q}/I₀−1 versus MPMP concentration based on the data in FIG. 2A. Using the Stern-Volmer equation provided above, a slope of about 1.6 is obtained by calculating k_{q}=(I_{q}/I₀−1)/([Q] T₀). This is a very low Stern-Volmer quenching constant, indicating that there is no significant quenching by MPMP.

FIG. 3A is a graph of the luminescence quenching behavior of NPB with Emitter I. The luminescence intensity was measured at NPB concentrations ranging from 0 M to 0.0031 M. The graph illustrates that although the NPB concentration was not varied over as wide of a range as in the case of MPMP in FIG. 2A, luminescence intensity changed more significantly in the case of NPB, ranging from around 5.2×10⁶ when there is no NPB to about 0.8×10⁶ at NPB concentration of 0.0031 M. The fact that intensity is more sensitive to NPB concentration than to MPMP concentration indicates that NPB has a higher quenching rate constant.

FIG. 3B is a graph of I_{q}/I₀−1 versus NPB concentration based on the data in FIG. 3A. Using the Stern-Volmer equation, a slope of about 1729 was obtained. This is a high quenching rate constant, which explains why device performance is poor when NPB is used as the hole transport material.

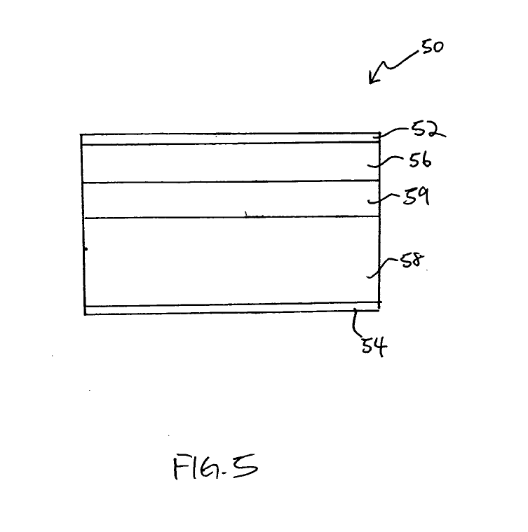

FIG. 4 is a graph of the Stern-Volmer quenching behavior for a number of hole transport materials. The graph shows that materials such as MPMP, and CBP have the lowest quenching constants, while materials such as TDATA and NPB make poor hole transport candidates for an Ir-based emitter. The Stern-Volmer quenching constants for these materials are listed in Table I.

TABLE I
Emitter I quenching by HTM

| | LED peak | LED peak | |
|---|---|---|---|
| HTM | efficiency, cd/A | radiance, cd/m2 | k_{q} · T₀ |
| MPMP | 25 | 8500 | 1.6 |
| 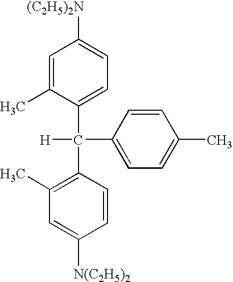 | | | |
| CBP | 15 | 32000 | 5.0 |
| 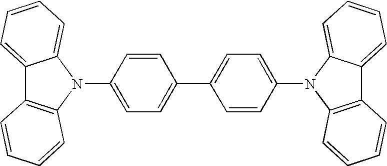 | | | |
| TPD | 16 | 3700 | 209 |
| 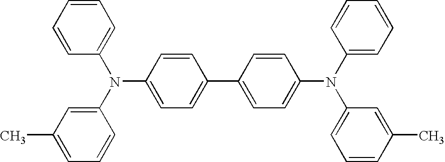 | | | |
| NBP | 1.5 | 1500 | 1729 |
| 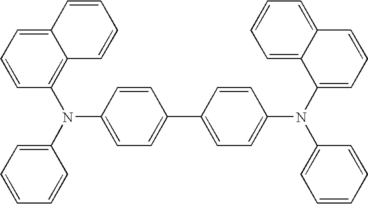 | | | |
| TDATA | 1.1 | 500 | 2179 |
| 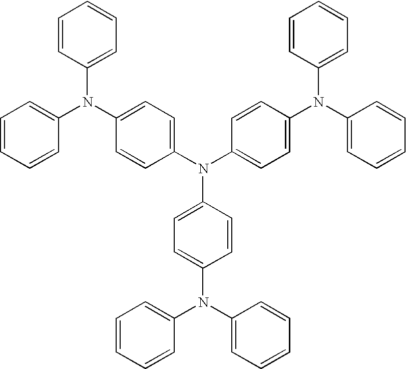 | | | |

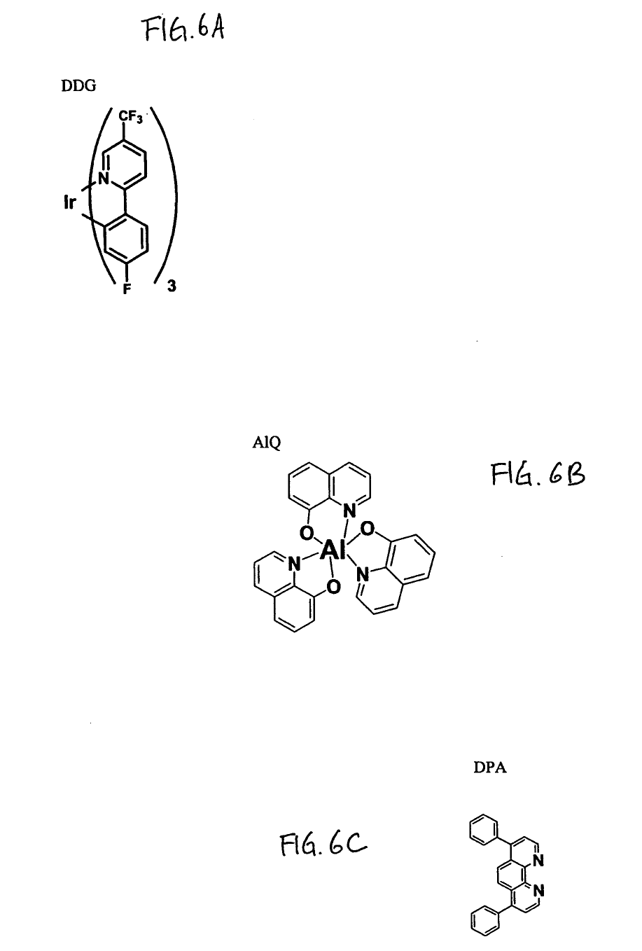

FIG. 5 depicts a typical device 50 for which the selection process 10 or the combinatorial selection process 60 may be used. The device 50 may be any device including at least one charge transport and/or anti-quenching material positioned between a photoactive layer and an electrode, such as an organic light emitting diode (OLED). The device 50 has an anode layer 52 and a cathode layer 54. Adjacent to the anode layer 52 is a hole transport material layer 56. Adjacent to the cathode layer 54 is an electron transport layer 58 (also referred to as anti-quenching layer). Depending on the electronic device, there may be more than one hole transport material layer 56 or more than one electron transport material layer 58. Between the hole transport layer 56 and the electron transport layer 58 is the photoactive layer 59. Each of these functional layers may be made of one or more physical layers or combined into one layer in certain devices.

Depending upon the application, the photoactive layer 59 may be made of any suitable electroluminescent material.

As described above, the photoactive layer 59 may include a material that is activated when a voltage is applied across the anode layer 52 and the cathode layer 54. Alternatively, the photoactive layer 60 may be a material that responds to radiant energy and generates a signal with or without an applied bias voltage, such as a photodetector. The selection process 50 may be used to determine the composition of the hole transport material layer 56.

An effective electron transport material for the electron transport material layer 58 may be an AlQ₃ derivative, a phenanthroline derivative, or a quinoxaline derivative. In some cases, it may be desirable to use an electron transport material that has the following properties, although the invention is not so limited:
1. The material has to be able to transport electrons efficiently, preferably at a mobility of >10⁻⁷ cm²/(V·sec).
2. The energy difference between the LUMO of the electron transport material and the work function of the cathode layer 54 has to be small enough to allow efficient electron injection from the cathode. The energy barrier is preferred to be less than 1 V (i.e., E1−E3<1V).
3. The LUMO level of the electron transport material has to be high enough to prevent it from receiving an electron from the photoactive layer 60. This usually requires E1−E2>−1 V and preferably E1−E2>0.
4. The HOMO level of the electron transport material has to be low enough to prevent it from donating an electron to the photoactive layer 60. This usually requires E4−E5>−1V and preferably E4−E5>0.

In the above criteria, E1 is the lowest un-occupied molecular orbital (LUMO) energy level of the electron transport material layer. E2 is the LUMO of the photoactive layer 60. E3 is the work function of the cathode, E4 is the highest occupied molecular orbital (HOMO) of the photoactive layer, and E5 is the HOMO of the electron transport material layer 58. All of the energy levels have negative value; they are referenced to the energy level at vacuum, at which point the energy level is defined to be zero. Higher energy means the energy level is closer to the level at vacuum. These energy levels can be measured in the solid state by techniques such as photoelectron spectroscopy. One can also use cyclic voltametry measurement in solution to measure the relative energy levels of the molecule.

The optimal energy level of the electron transport material in criteria 3 and 4 described above can be determined by the application of electron transfer theory. The rate of electron transfer reaction as a function of energy difference is described by Marcus theory (see, e.g., R. A. Marcus et al, J. Phys. Chem., 86, 622 (1982)). Examples of electron transport materials include metal chelated oxinoid compounds, such as tris (8-hydroxyquinolato) aluminum(Alq3), azole compounds such as 2-(4-biphenylyl)-5-(4-t-butylphenyl)1,3,4-oxadiazole (PBD) and 3-(4-biphenylyl)-4-phenyl-5-(4-t-butylphenyl)-1,2,4-triazole (TAZ).

The anode layer 52 may be made of any conventional material such as a metal, mixed metal, alloy, metal oxide or mixed-metal oxide, or a conductive polymer. Suitable metals include the Group 1 metals, the metals in Groups 4, 5, 6, and the Group 8-10 transition metals. If the anode layer 52 is to be light-transmitting, mixed-metal oxides of Group 12, 13, and 14 metals, such as indium-tin-oxide, may be used. The anode layer 52 may also include an organic material such as polyaniline as described in “Flexible light-emitting diodes made from soluble conducting polymer,” Nature, vol. 357, pp. 477479 (11 Jun. 1992). At least one of the anode layer 52 and the cathode layer 54 should be at least partially transparent to allow the emitted light to escape the device.

The cathode layer 54 may be made of any material having a lower work function than the anode layer 52. Materials for the cathode layer 54 may be selected from alkali metals of Group 1, Group 2 metals, Group 12 metals including rare earth elements, lanthanides and actinides, materials such as aluminum, indium, calcium, barium, samarium and magnesium, and combinations thereof. Li-containing organometallic compounds, LiF, and Li₂O may also be deposited between the organic layer and the cathode layer to lower the operating voltage.

The hole transport material layer 56 may be made of any of the materials listed in Table I. However, as indicated by the different quenching rate constant values, not all hole transport materials work well with a given photoactive layer 59. The data in Table I are obtained using a light emitting diode device having the following configuration:
HTM(300 Å)/Emitter 1(400 Å)/DPA
(100 Å)/AlQ(300 Å)/LiF(10 Å)/Al(400 Å).

The peak radiance and efficiency of these devices are summarized in Table I, along with the Stern-Volmer quenching constants. As Table I indicates, the hole transport material (HTM) with a large quenching constant tends to give poor LED performance, while an HTM with a small quenching constant tends to yield devices with better efficiency/radiance.

Although the invention is described in the context of a light emitting diode, it will be appreciated that the aforementioned embodiments are provided by way of example only to illustrate the general principles of the invention. Various changes, substitutions, and alternations can be made without departing from the principles and the scope of the invention, the scope of which is defined in the appended claims.

1. A charge transport or anti-quenching materials selected by the method comprising:
(a) determining a first luminescence intensity I₀ of a luminescent material in the absence of the charge transport and/or anti-quenching material;
(b) determining a second luminescence intensity I_{q} of the luminescent material in the presence of the charge transport and/or anti-quenching material; and
(c) comparing the first luminescence intensity I₀ with the second luminescence intensity I_{q} to determine a degree of luminescence quenching of the charge transport and/or anti-quenching material with respect to the luminescent material; and
(d) determining whether the degree of quenching is appropriate for the desired electronic device of said charge transport and/or anti-quenching material.

2. The material of claim 1, wherein the first luminescence intensity I₀ is compared with the second luminescence intensity I_{q} by visual observation.

3. The material of claim 1 selected using a visual observation of photoluminescence in step (c) that the second luminescence intensity I_{q} is comparable to the first luminescence intensity I₀.

4. The material of claim 1, selected by the method wherein comparing the first luminescence intensity I₀ with the second luminescence intensity I_{q} in step (c) is done using a photodetector.

5. The material of claim 1, selected wherein determining the first luminescence intensity I₀ comprises preparing a solution having a luminescent material concentration of approximately 10⁻⁶ M to 10⁻²M.

6. The method of claim 1, wherein determining the second luminescence intensity comprises adding a fixed concentration [Q] of up to about 2.0 M of the charge transport and/or anti-quenching material to a solution of the luminescent material.

7. The material of claim 1 selected by the method further comprising determining the second luminescence intensity I_{q} at a plurality of different concentrations of the charge transport and/or anti-quenching material to determine a sensitivity of the second luminescence intensity I_{q} to a concentration of the charge transport and/or anti-quenching material.

8. The method of claim 7 further comprising:
preparing a plot of I_{q}/I₀−1 against a concentration [Q] of a charge transport and/or anti-quenching material; and
determining the Stern-Volmer luminescence quenching constant based on a slope of the plot and an equation (I_{q}/I₀)−1=k_{q}T₀[Q].

9. The method of claim 1, selected by the method further comprising selecting the charge transport and/or anti-quenching material having a low degree of luminescence quenching.

10. The material of claim 8, selected by the method further comprising selecting the charge transport and/or anti-quenching material having a low Stern-Volmer luminescence quenching constant.

11. The material of claim 8, wherein the low Stern-Volmer luminescence quenching constant has a value less than 500.

12. The method of claim 8, wherein the low Stern-Volmer luminescence quenching constant has a value less than 100.

13. The material of claim 1, selected by the method wherein the first luminescence intensity 10 and the second luminescence intensity I_{q} are determined under substantially anaerobic conditions.

14. The material of claim 1, selected by the method wherein the luminescent material is a fluorescent compound or an organometallic compound.

15. The material of claim 14, selected by the method wherein the organometallic compound has a metal selected from metals selected from those that are in Group 3 through 15 of the Periodic Table and mixtures thereof and the fluorescent compound is AlQ₃.

16. The material of claim 1, wherein the charge transport and/or anti-quenching material is a hole transport material or an electron transport material.

17. An organic electronic device wherein at least one charge transport or anti-quenching materials is selected based on a degree of luminescence quenching as determined by the method of claim 1.

18. An electronic device of claim 17, wherein at least one of the materials selected has a Stern-Volmer luminescence quenching constant less than 500.

19. A kit comprising:
(a) a means for holding one or more test compartments containing therein 10⁻² to 10⁻⁶ Molar of light-emitting material;
(b) a charge transport/anti-quenching dispensing means; and
(c) a light source.

20. The kit according to claim 19, wherein the kit further contains a CCD camera.

21. A kit according to claim 19, wherein the light emitter is an organometallic complex.

22. A kit according to claim 19, wherein the charge transport material is selected from the group consisting of MPMP, CBP, TPD, NBP, TDATA, and mixtures thereof.
